(19) United States
(12) Patent Application Publication
(10) Pub. No.: US 2016/0174417 A1
(43) Pub. Date: Jun. 16, 2016

(54) COOLING SYSTEM AND METHOD FOR CONTROLLING REFRIGERANT SUPPLY VOLUME IN COOLING SYSTEM

(71) Applicant: NEC CORPORATION, Tokyo (JP)

(72) Inventors: Mahiro HACHIYA, Tokyo (JP); Minoru YOSHIKAWA, Tokyo (JP); Hitoshi SAKAMOTO, Tokyo (JP); Akira SHOUJIGUCHI, Tokyo (JP); Masaki CHIBA, Tokyo (JP); Kenichi INABA, Tokyo (JP); Arihiro MATSUNAGA, Tokyo (JP)

(73) Assignee: NEC Corporation, Tokyo (JP)

(21) Appl. No.: 14/903,205

(22) PCT Filed: Jul. 10, 2014
(86) PCT No.: PCT/JP2014/003668

§ 371 Date: Jan. 6, 2016

(30) Foreign Application Priority Data
Jul. 12, 2013 (JP) 2013-146401

(51) Int. Cl. H05K 7/20

(52) U.S. Cl. CPC H05K 7/20836; H05K 7/20736; H05K 7/208

(57) ABSTRACT

A control mechanism becomes complex when an optimum volume of refrigerant is stably supplied to a plurality of objects to be cooled that have differing heat generation values. The present invention is a cooling system which comprises a first refrigerant tank that stores a liquid-phase refrigerant, a plurality of evaporators that gasify the liquid-phase refrigerant supplied from the first refrigerant tank, a condenser that liquefies the gas-phase refrigerant that was gasified by the evaporators, a vapor pipe that connects the evaporators and the condenser and in which the gas-phase refrigerant flows, and a liquid pipe that connects the condenser and the first refrigerant tank and connects the first refrigerant tank and the plurality of evaporators and in which the liquid-phase refrigerant flows, wherein the condenser is located higher than the plurality of evaporators, and the first refrigerant tank is located lower than the condenser.

### TECHNICAL FIELD

The present invention relates to a cooling system and a method for controlling a refrigerant supply volume in the cooling system, and in particular relates to a cooling system to a plurality of heat generation sources and a method for controlling a refrigerant supply volume in the cooling system.

### BACKGROUND ART

A large number of electronic devices are installed in a server rack in a data center. The date center is composed by allocating a large number of such server racks. In a general data center, an air conditioner is used, the room temperature is lowered by supplying a cooling wind, and thereby the large number of electronic devices which generate heat in operation are cooled. However, in recent years, an amount of heat generated by the electronic device increases and the electronic device is highly integrated, and thereby the power consumption of the air conditioner increases. The amount of heat generated by the electronic device is different from each electronic device because a type or an operation rate thereof is different from each other, and thereby a point called as “a hot spot” at which the local temperature is higher than the surrounding area is generated. In order to deal with the hot spot, when the air conditioner is used for further lowering the room temperature, a large amount of electric power is required for operating the air conditioner.

It is known such a method in which a cooler is placed in the vicinity of the heat generation source for cooling, without using the air conditioner to cool the entire of installed environment. Patent Literature 1 (PTL1) proposes a method in which a refrigerant for cooling is circulated from a shared cooling tower to a plurality of servers installed in a server room placed on a plurality of floors, and thereby the electronic device in the server installed in the server room is cooled.

FIG. 10 is a configuration diagram showing a main part extracted from a drawing in Patent Literature 1 (PTL1). The relevant cooling system disclosed in Patent Literature 1 (PTL1) is used for cooling the electronic devices installed in a server room 301 and a server room 302 that are placed on a first floor and a second floor of a two-story building 300, respectively. A plurality of servers 303 are installed on a floor surface 301a of the server room 301 and a floor surface 302a of the server room 302. Evaporators 304 are arranged near the servers 303, respectively. A temperature sensor 312b for detecting the temperature around it and a valve 313b inserted in a pipe laid near each evaporator 304 are provided for each evaporator 304. A cooling tower 307 is placed on the roof of the building 300.

In Patent Literature 1 (PTL1), a refrigerant is sent to the evaporator 304 on each floor from the cooling tower 307 through a supply pipe 305. The refrigerant flowing in a cooling coil inside the evaporator 304 is evaporated by high-temperature air generated by the server 303, and thereby the vaporization heat is taken from the surrounding air and the refrigerant gasifies. As a result, the server 303 itself and the high-temperature air discharged from the server 303 are cooled. The refrigerant gasified by each evaporator 304 is sent to the cooling tower 307 through a return pipe 306. In the cooling tower 307, the gasified refrigerant is cooled by water or air, condensed, and liquefied.

In Patent Literature 1 (PTL1), a heat exchanger 308 is further connected to the supply pipe 305 and the return pipe 306 in parallel to the cooling tower 307. Another cooling tower 310 is connected to the heat exchanger 308 via a refrigerating machine 309. The temperature is detected by a temperature sensor 312a provided midway in the pipe of the cooling tower 307 and the pipe of the heat exchanger 308 and a plurality of valves 313a arranged midway in the pipe are controlled by a control unit 311 according to a detected result. By adjusting an opening amount of the valve 313a, a volume of the refrigerant to be flowed in the heat exchanger 308 is controlled. Further, the temperature near each evaporator 304 is detected by the temperature sensor 312b and the valve 313b of the pipe of each evaporator 304 is controlled according to a detected result.

In Patent Literature 1 (PTL1), the cooling tower 307 and the heat exchanger 308 are placed on the roof of the building 300 and the refrigerant from the cooling tower 307 and the heat exchanger 308 is sent in the building 300, in other words, it is sent to the evaporator 304 located at a position lower than that of the cooling tower 307 or the heat exchanger 308. The refrigerant is naturally circulated between the evaporator 304 and the cooling tower 307, and thereby the cooling is performed.

Patent Literature 2 (PTL2) relates to an air-conditioning system, and proposes a phase-change cooler which transports heat by using latent heat required when phase change of refrigerant occurs. The phase-change cooler in Patent Literature 2 (PTL2) includes an evaporation unit which receives heat from a heat generator and changes the phase of the refrigerant from a liquid phase to a gas phase and a condensation unit which takes the heat of the gas-phase refrigerant by an external fan or the like and changes the phase of the refrigerant from the gas phase to the liquid phase. The phase-change cooler in Patent Literature 2 (PTL2) further includes a pipe which connects the evaporation unit and the condensation unit, and the refrigerant which is circulated in the pipe in a completely closed state.

Patent Literature 3 (PTL3) relates to an ebullient cooling type cooling device. Patent Literature 3 (PTL3) describes that heat generated by a power conversion device that is an object to be cooled is sent to a boiling container, in the boiling container, the refrigerant in a liquid state is changed to a vapor by the heat generated by the power conversion device, and the heat generated by the latent heat is absorbed. Further, it is described that the heat of the gas-phase refrigerant generated in the boiling container is lost by a heat exchange operation, the refrigerant is condensed and liquefied, the generated liquid flows in a sloping heat-transfer tube and the liquid-phase refrigerant is generated, and the liquid-phase refrigerant goes back to the boiling container. It is described that a cycle in which the refrigerant evaporates in the boiling container and condenses in the heat-transfer tube is repeated, and thereby the heat generated by the power conversion device is discharged.

### CITATION LIST

### Patent Literature

[PTL 1] Japanese Patent Application Laid-Open No. 2009-194093

[PTL 2] Japanese Patent Application Laid-Open No. 2007-127315

[PTL 3] Japanese Patent Application Laid-Open No. 2012-54316

### SUMMARY OF INVENTION

### Technical Problem

However, the cooling system, the air-conditioning system, and the cooling device described in the background art have the following problem.

First, the amount of heat generated by the electronic device is different from each electronic device because a type or an operation rate thereof is different from each other, and thereby the amount of heat generated by a server rack unit is different for each server rack unit. In a case that when cooling is performed by transporting heat using circulation of refrigerant having phase-change characteristic, cooling efficiency is lowered if shortage of the refrigerant occurs. In a case in which the phase of the refrigerant is changed, the refrigerant is circulated, the heat is transported, and cooling is performed, when a shortage of the refrigerant occurs, cooling efficiency is reduced. Further, when the refrigerant is excessively supplied, the cooling efficiency is also lowered because of the increase of the boiling point with the increase of an internal pressure or the like. As described above, when the phase-change cooler is used, it becomes important to supply an optimum volume of refrigerant that matches with the generated heat amount. In order to optimize the refrigerant supply volume, a complicated control mechanism is needed as in Patent Literature 1 such that a temperature sensor and a valve are provided for each evaporator and the refrigerant supply volume is controlled.

Secondly, even when the refrigerant supply volume is controlled for each server rack unit in response to variation in amount of heat generated by the server rack unit, the control mechanism as in Patent Literature 1 cannot deal with variation in amount of heat generated by unit of the electronic device (or for each height) installed in the server rack. For this reason, optimized cooling cannot be performed, and thereby a hot spot may occur.

Such problem cannot be solved even by using the air-conditioning system in Patent Literature 2 or the cooling device in Patent Literature 3. In Patent Literature 3, only one boiling container is used in a closed system in which the refrigerant is circulated. Therefore, Patent Literature 3 does not show such a structure that a plurality of boiling containers are equipped in the closed system and in which an optimum volume of the refrigerant is supplied to each boiling container.

It is an object of the present invention to provide a cooling system which can solve the above-mentioned problem in which a control mechanism becomes complex when an optimum volume of refrigerant is stably supplied to a plurality of objects to be cooled that have differing heat generation values and a method for controlling refrigerant supply volume in the cooling system.

### Solution to Problem

In order to achieve the above-mentioned object, a cooling system according to the present invention includes a first refrigerant tank which stores a liquid-phase refrigerant, a plurality of evaporation units which gasify the liquid-phase refrigerant supplied from the first refrigerant tank, a condensation unit which liquefies a gas-phase refrigerant gasified by the evaporation unit, a vapor pipe which connects the evaporation unit and the condensation unit and in which the gas-phase refrigerant flows, and a liquid pipe which connects the condensation unit and the first refrigerant tank and connects the first refrigerant tank and a plurality of the evaporation units and in which the liquid-phase refrigerant flows.

The condensation unit is arranged at a position higher than those of a plurality of the evaporation units and the first refrigerant tank is arranged at a position lower than that of the condensation unit.

A method for controlling a refrigerant supply volume in a cooling system according to the present invention includes a step of controlling a volume of liquid-phase refrigerant supplied to an evaporation unit by changing an arrangement of a refrigerant tank in a vertical direction in the cooling system which includes a refrigerant tank which stores the liquid-phase refrigerant, a plurality of evaporation units which gasify the liquid-phase refrigerant supplied from the refrigerant tank, a condensation unit which liquefies a gas-phase refrigerant gasified by the evaporation unit, a vapor pipe which connects the evaporation unit and the condensation unit and in which the gas-phase refrigerant flows, and a liquid pipe which connects the condensation unit and the refrigerant tank and connects the refrigerant tank and a plurality of the evaporation units and in which the liquid-phase refrigerant flows.

### Advantageous Effects of Invention

By using a cooling system and a method for controlling refrigerant supply volume in a cooling system according to the present invention, an optimum volume of refrigerant can be stably supplied to a plurality of objects to be cooled, each of which has a different heat generation amount from each other, without using a complicated control mechanism.

### BRIEF DESCRIPTION OF DRAWINGS

FIG. 1 is a configuration diagram showing a cooling system according to a first exemplary embodiment of the present invention.

FIG. 2 is a configuration diagram showing a cooling system according to a second exemplary embodiment of the present invention.

FIG. 3 is a configuration diagram showing a cooling system according to a third exemplary embodiment of the present invention.

FIG. 4 is a configuration diagram showing a cooling system according to a fourth exemplary embodiment of the present invention.

FIG. 5 is a configuration diagram showing a cooling system according to a fifth exemplary embodiment of the present invention.

FIG. 6 is a configuration diagram showing a cooling system according to a sixth exemplary embodiment of the present invention.

FIG. 7 is a configuration diagram showing a cooling system according to a seventh exemplary embodiment of the present invention.

FIG. 8 is a configuration diagram showing a cooling system according to an eighth exemplary embodiment of the present invention.

FIG. 9 is a configuration diagram showing a cooling system according to a ninth exemplary embodiment of the present invention.

FIG. 10 is an explanatory drawing showing a related cooling system.

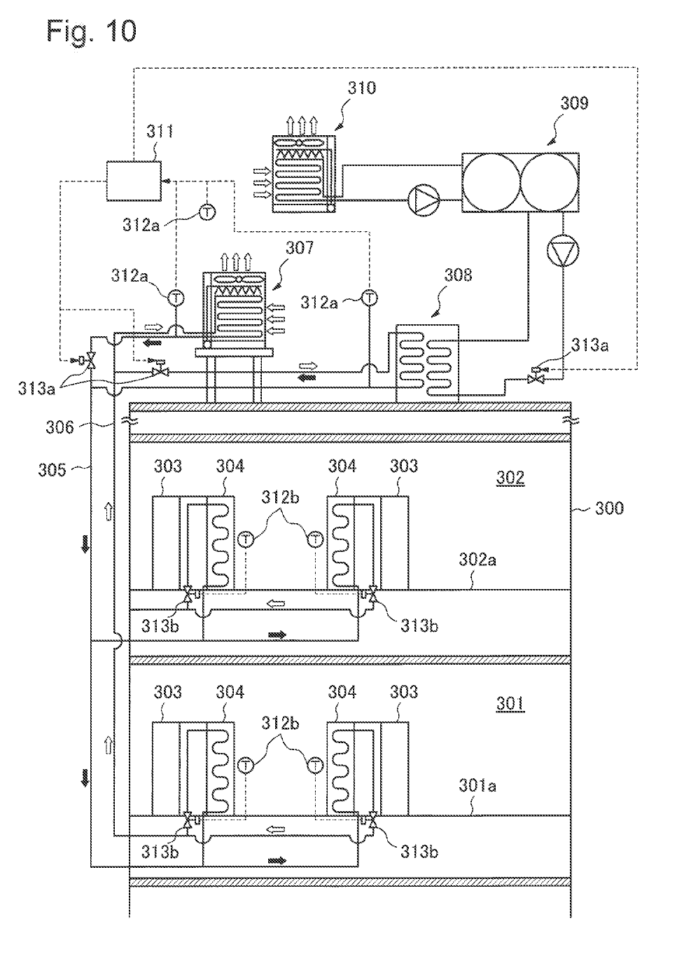

### DESCRIPTION OF EMBODIMENTS

A preferred exemplary embodiment of the present invention will be described in detail with reference to drawings. In the following explanation, a case in which a plurality of server racks in which an electronic device is installed are cooled will be explained as an example.

### First Exemplary Embodiment

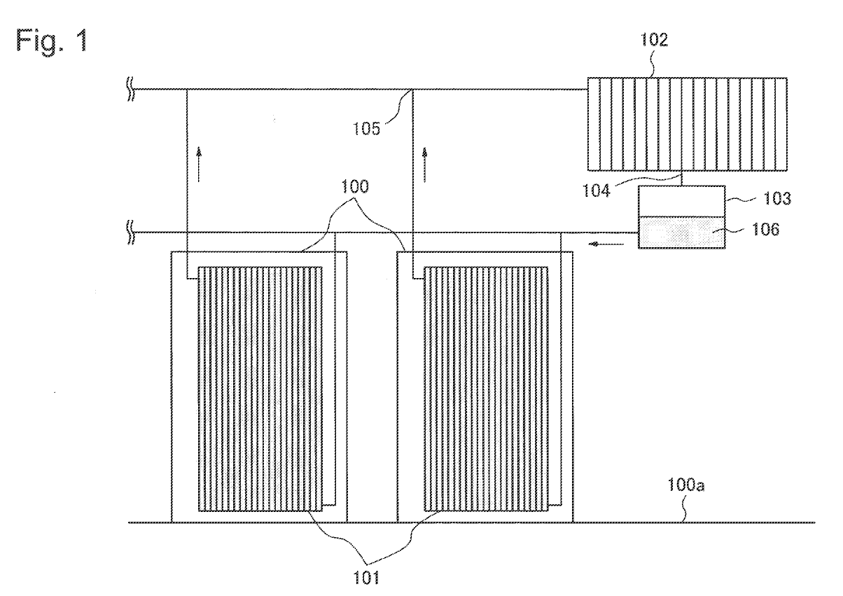

First, a cooling system according to a first exemplary embodiment of the present invention and a method for controlling refrigerant supply volume in the cooling system will be described. FIG. 1 is a configuration diagram showing the cooling system according to the first exemplary embodiment of the present invention.

As shown in FIG. 1, the cooling system according to this exemplary embodiment includes a refrigerant tank 103 provided as an example of a first refrigerant tank which stores a liquid-phase refrigerant 106 and a plurality of evaporation units 101 which gasify the liquid-phase refrigerant supplied from the refrigerant tank 103. Further, the cooling system according to this exemplary embodiment includes a condensation unit 102 which liquefies a gas-phase refrigerant gasified by a plurality of the evaporation units 101, and a vapor pipe 105 which connects the evaporation unit 101 and the condensation unit 102 and in which the gas-phase refrigerant flows. Further, the cooling system according to this exemplary embodiment includes a liquid pipe 104 which connects the condensation unit 102 and the refrigerant tank 103 and connects the refrigerant tank 103 and a plurality of the evaporation units 101 and in which the liquid-phase refrigerant flows.

Here, the condensation unit 102 is arranged at a position higher than those of a plurality of the evaporation units 101 in a vertical upper direction as an example of the upper side, and the refrigerant tank 103 is arranged at a position lower than that of the condensation unit 102 in a vertical lower direction as an example of the lower side. The refrigerant tank 103 is arranged at a position higher than those of a plurality of the evaporation units 101 when viewed from an installation surface 100a of a plurality of server racks 100. A heat exchange machine such as a radiator or the like can be used as a plurality of the evaporation units 101 and the condensation unit 102.

A plurality of the evaporation units 101 are arranged on the rear surface or the front surface of the server rack 100. FIG. 1 shows a case in which two server racks 100 whose outer shapes are vertically long are installed and one evaporation unit 101 whose outer shape is vertically long is arranged for each server rack 100. The electronic device that is a heat generation source is installed in the server rack 100. Each evaporation unit 101 is a heat receiving unit which receives heat of the high-temperature air generated by the heat generation source.

The liquid pipe 104 connects a lower part of the condensation unit 102 and an upper part of the refrigerant tank 103, and connects a lower part of the side surface of the refrigerant tank 103 and a lower part of each evaporation unit 101. The vapor pipe 105 connects an upper part of each evaporation unit 101 and an upper part of the condensation unit 102. The refrigerant 106 is enclosed in such closed system.

In the cooling system according to this exemplary embodiment, the liquid-phase refrigerant is supplied to each evaporation unit 101 by the gravity naturally. The level of liquid in each evaporation unit 101 is determined by the level of liquid in the refrigerant tank 103, and does not depend on an amount of heat generated by the electronic device installed in each server rack 100. FIG. 1 shows a state in which all the evaporation units 101 are always filled with the refrigerant. In the cooling system according to this exemplary embodiment, a volume of refrigerant supplied to each evaporation unit 101 can be uniformly controlled by controlling the level of liquid in the refrigerant tank 103, and the controlling the level of liquid in the refrigerant tank 103 is performed by changing the installation position of the refrigerant tank 103 along the vertical direction.

Further, in FIG. 1, each liquid pipe 104 and the vapor pipe 105 are drawn as lines extending in the vertical direction or the horizontal direction. However, it is not necessary to place each liquid pipe 104 and the vapor pipe 105 in a completely vertical direction or a completely horizontal direction.

### Second Exemplary Embodiment

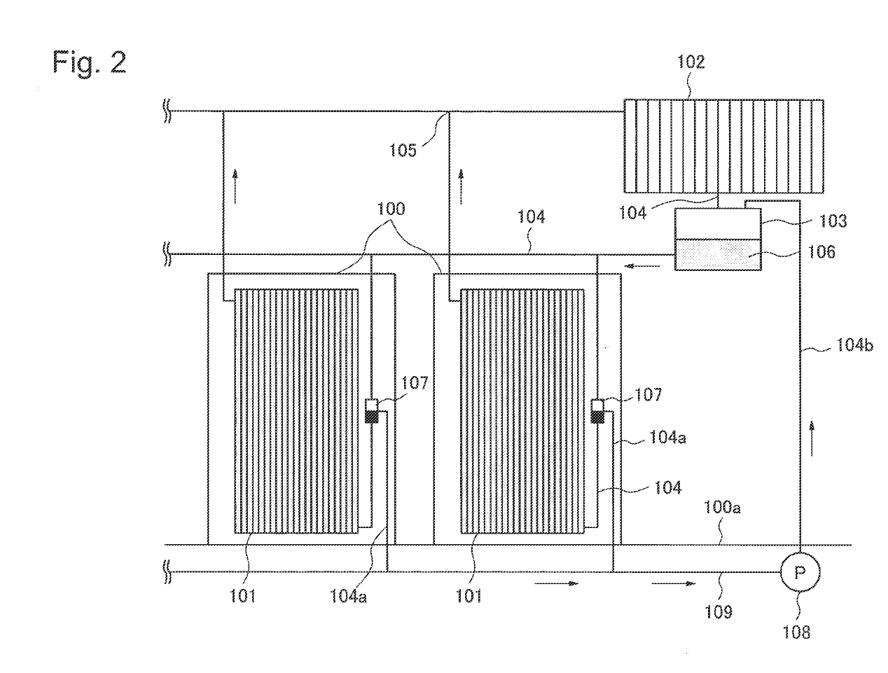

Next, a cooling system according to a second exemplary embodiment of the present invention and a method for controlling a refrigerant supply volume in the cooling system will be described. FIG. 2 is a configuration diagram showing the cooling system according to the second exemplary embodiment of the present invention. The same reference numbers are added to elements similar to the first exemplary embodiment, and thereby the detailed description of the element will be omitted. This exemplary embodiment is a modification example of the first exemplary embodiment. In this exemplary embodiment, a second refrigerant tank is provided for each evaporation unit.

As shown in FIG. 2, the cooling system according to this exemplary embodiment includes the refrigerant tank 103 provided as an example of the first refrigerant tank which stores the liquid-phase refrigerant 106 and a plurality of evaporation units 101 which gasify the liquid-phase refrigerant supplied from the refrigerant tank 103 like the first exemplary embodiment. Further, the cooling system according to this exemplary embodiment includes the condensation unit 102 which liquefies the gas-phase refrigerant gasified by a plurality of the evaporation units 101 and the vapor pipe 105 which sends the gas-phase refrigerant to the condensation unit 102. Further, the cooling system according to this exemplary embodiment includes the liquid pipe 104 which sends the liquid-phase refrigerant to the refrigerant tank 103 and sends the liquid-phase refrigerant to a plurality of the evaporation units 101 from the refrigerant tank 103. The condensation unit 102 is arranged at a position higher than those of a plurality of the evaporation units 101 in the vertical upper direction as an example of the upper side, and the refrigerant tank 103 is arranged at a position lower than that of the condensation unit 102 in the vertical lower direction as an example of the lower side like the first exemplary embodiment.

The cooling system according to this exemplary embodiment further includes second refrigerant tanks 107, a refrigerant recovery pipe 109, a pump 108, and liquid pipes 104a and 104b. The second refrigerant tank 107 is provided to the pipe 104 connecting the refrigerant tank 103 and each evaporation unit 101 and arranged at a position lower than that of the refrigerant tank 103 in the vertical lower direction as an example of the lower side. In other words, in this exemplary embodiment, the second refrigerant tank 107 is provided for each server rack 100. As a result, the refrigerant 106 is supplied to each evaporation unit 101 via the second refrigerant tank 107.

The liquid pipe 104a is branched off from the liquid pipe 104 near the midpoint of the side surface of each second refrigerant tank 107, and the liquid pipe 104a is connected to the refrigerant recovery pipe 109 arranged in a space under an installation surface 100a of the server rack 100, for example, an underfloor space or the like. The refrigerant recovery pipe 109 is connected to the refrigerant tank 103 via the liquid pipe 104b, and the pump 108 is arranged between the refrigerant recovery pipe 109 and the liquid pipe 104b.

In the cooling system according to this exemplary embodiment, a part of the refrigerant 106 in the second refrigerant tank 107 is discharged from near the midpoint of the side surface of the second refrigerant tank 107 to the refrigerant recovery pipe 109 through the liquid pipe 104a. The refrigerant discharged to the refrigerant recovery pipe 109 is returned to the refrigerant tank 103 via the liquid pipe 104b by an operation of the pump 108. Namely, the refrigerant discharged to the refrigerant recovery pipe 109 is pumped up by the pump 108 and returned to the refrigerant tank 103.

Further, in a case in which a data center is of plural-story construction and there is a server room in the downstairs floor, the pump 108 is not used and the refrigerant discharged to the refrigerant recovery pipe 109 may be sent to the refrigerant tank in the downstairs server room. The refrigerant recovery pipe 109 is extended also toward a left direction in paper of FIG. 2. In a case in which there is a server room in the downstairs floor, the refrigerant recovery pipe 109 extending toward the left direction in paper of FIG. 2 may be connected to the refrigerant tank in the downstairs server room.

In the cooling system according to this exemplary embodiment, the liquid-phase refrigerant is supplied to each evaporation unit 101 by the gravity naturally like the first exemplary embodiment. The level of liquid in each evaporation unit 101 is determined by the level of liquid in the second refrigerant tank 107, and does not depend on an amount of heat generated by the electronic device installed in each server rack 100. In this exemplary embodiment, the volume of refrigerant supplied to the evaporation unit 101 can be optimized by controlling the level of liquid in the second refrigerant tank 107, and the controlling the level of liquid in the second refrigerant tank 107 is performed by changing the installation position of the second refrigerant tank 107 along the vertical direction.

Further, in the cooling system according to this exemplary embodiment, the surplus refrigerant 106 in the second refrigerant tank 107 is discharged to the refrigerant recovery pipe 109 through the branched liquid pipe 104a. As a result, the level of liquid in the second refrigerant tank 107 is kept to a constant level that is equal to a height of a branching point. As a result, the volume of refrigerant supplied to a plurality of the evaporation units 101 becomes more stable.

In the first exemplary embodiment, the volume of refrigerant supplied to each evaporation unit 101 is controlled on the basis of the level of liquid in the refrigerant tank 103. However, when this exemplary embodiment is used, the volume of refrigerant supplied to each evaporation unit 101 can be controlled on the basis of the level of liquid in the second refrigerant tank 107. As a result, the volume of refrigerant supplied to each evaporation unit 101 can be optimized.

### Third Exemplary Embodiment

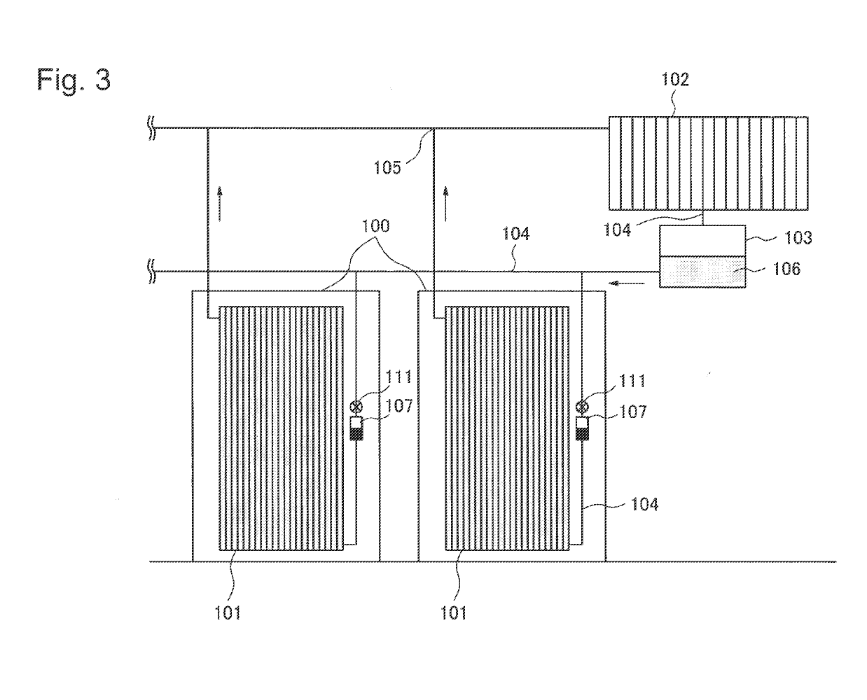

Next, a cooling system according to a third exemplary embodiment of the present invention and a method for controlling a refrigerant supply volume in the cooling system will be described. FIG. 3 is a configuration diagram showing the cooling system according to the third exemplary embodiment of the present invention. The same reference numbers are added to elements similar to the first exemplary embodiment or the second exemplary embodiment, and thereby the detailed description of the element will be omitted. This exemplary embodiment is a modification example of the second exemplary embodiment. In this exemplary embodiment, a refrigerant control mechanism is provided for each second refrigerant tank.

As shown in FIG. 3, the cooling system according to this exemplary embodiment includes the refrigerant tank 103 provided as an example of the first refrigerant tank which stores the liquid-phase refrigerant 106 and a plurality of the evaporation units 101 which gasify the liquid-phase refrigerant supplied from the refrigerant tank 103 like the first exemplary embodiment or the second exemplary embodiment. Further, the cooling system according to this exemplary embodiment includes the condensation unit 102 which liquefies the gas-phase refrigerant gasified by a plurality of the evaporation units 101 and the vapor pipe 105 which sends the gas-phase refrigerant to the condensation unit 102. Further, the cooling system according to this exemplary embodiment includes the liquid pipe 104 which sends the liquid-phase refrigerant to the refrigerant tank 103 and sends the liquid-phase refrigerant to a plurality of the evaporation units 101 from the refrigerant tank 103. The condensation unit 102 is arranged at a position higher than those of a plurality of the evaporation units 101 in the vertical upper direction as an example of the upper side and the refrigerant tank 103 is arranged at a position lower than that of the condensation unit 102 in the vertical lower direction as an example of the lower side like the first exemplary embodiment or the second exemplary embodiment. Further, the cooling system according to this exemplary embodiment includes the second refrigerant tank 107 like the second exemplary embodiment. The second refrigerant tank 107 is provided to the pipe 104 connecting the refrigerant tank 103 and each evaporation unit 101, and arranged at a position lower than that of the refrigerant tank 103 in the vertical lower direction as an example of the lower side.

The cooling system according to this exemplary embodiment further includes a refrigerant control mechanism, which controls the refrigerant supply volume according to the level of liquid in the second refrigerant tank 107, provided between the refrigerant tank 103 and a plurality of the second refrigerant tanks 107. Specifically, the refrigerant control mechanism is a refrigerant supply volume suppression mechanism 111 which suppresses the refrigerant supply volume according to the level of liquid in the second refrigerant tank 107. As this refrigerant supply volume suppression mechanism 111, a float valve, a ball tap or the like can be used. The refrigerant 106 is supplied to each evaporation unit 101 from the refrigerant tank 103 via the second refrigerant tank 107.

In the cooling system according to this exemplary embodiment, the liquid-phase refrigerant is supplied to each evaporation unit 101 by the gravity naturally like the first exemplary embodiment or the second exemplary embodiment. The level of liquid in each evaporation unit 101 is determined by the level of liquid in the second refrigerant tank 107, and does not depend on an amount of heat generated by the electronic device installed in each server rack 100 like the second exemplary embodiment. By using this exemplary embodiment, the volume of refrigerant supplied to the evaporation unit 101 can be optimized by controlling the level of liquid in the second refrigerant tank 107, and the controlling the level of liquid in the second refrigerant tank 107 is performed by changing the installation position of the second refrigerant tank 107 along the vertical direction or by another method.

Further, in this exemplary embodiment, the refrigerant supply volume suppression mechanism 111 monitors the level of liquid in the second refrigerant tank 107 and when the level of liquid is higher than a predetermined level, the refrigerant supply volume suppression mechanism 111 suppresses the volume of refrigerant supplied to the second refrigerant tank 107. By using this refrigerant supply volume suppression mechanism 111, it becomes possible to control the level of liquid in the second refrigerant tank 107, and thereby the volume of refrigerant supplied to each evaporation unit 101 becomes more stable.

### Fourth Exemplary Embodiment

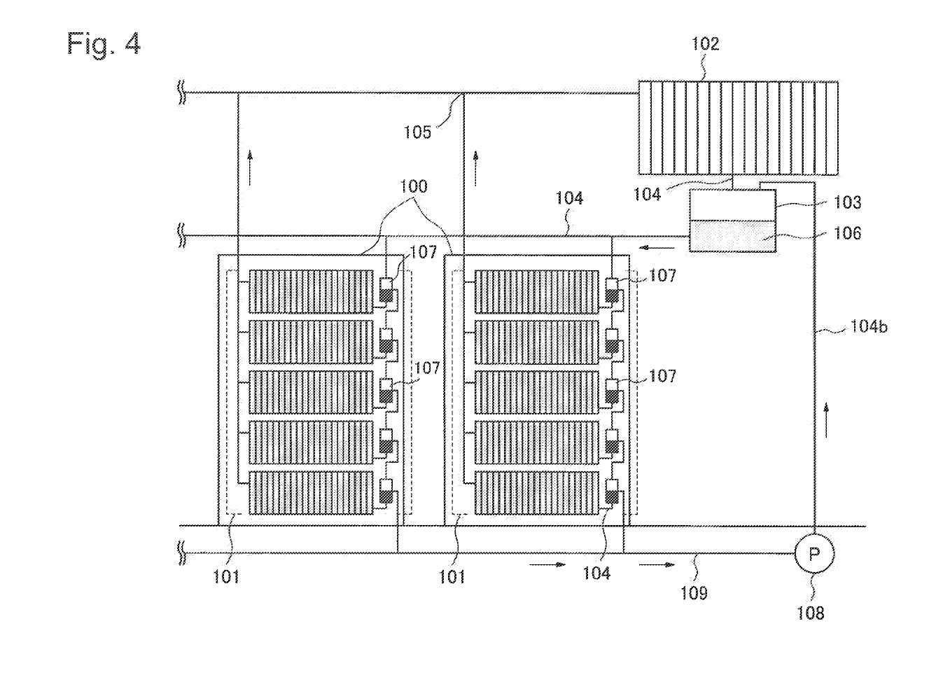

Next, a cooling system according to a fourth exemplary embodiment of the present invention and a method for controlling a refrigerant supply volume in the cooling system will be described. FIG. 4 is a configuration diagram showing the cooling system according to the fourth exemplary embodiment of the present invention. The same reference numbers are added to elements similar to the first to third exemplary embodiments, and thereby the detailed description of the element will be omitted. In the cooling system according to this exemplary embodiment, the evaporation units 101 and the second refrigerant tanks 107 according to the second exemplary embodiment are installed in multi-stage in a height direction.

As shown in FIG. 4, in the cooling system according to this exemplary embodiment, two server racks 100 whose outer shapes are vertically long are installed and a plurality of evaporation units 101 whose outer shapes are horizontally long are arranged in each of two server racks 100. FIG. 4 shows a case in which five evaporation units 101 are arranged in one server rack 100.

The second refrigerant tank 107 is arranged for each of five evaporation units 101. The refrigerant 106 in the second refrigerant tank 107 is supplied to the evaporation unit 101 from the bottom surface of the second refrigerant tank 107 through the liquid pipe 104. A part of the refrigerant 106 in the second refrigerant tank 107 is sent to another second refrigerant tank 107 arranged at a position lower than that of the second refrigerant tank 107 in the vertical lower direction as an example of the lower side by the branched liquid pipe that is branched off from the liquid pipe 104 near the midpoint of the side surface of the second refrigerant tank 107. A part of the refrigerant 106 in the second refrigerant tank 107 arranged in the lowermost stage among the second refrigerant tanks 107 installed in multi-stage in a height direction is discharged from near the midpoint of the side surface of each second refrigerant tank 107 to the refrigerant recovery pipe 109 through the liquid pipe. The refrigerant discharged to the refrigerant recovery pipe 109 is returned to the refrigerant tank 103 via the liquid pipe 104b by the operation of the pump 108.

In the cooling system according to this exemplary embodiment, the liquid-phase refrigerant is supplied to each evaporation unit 101 by the gravity naturally like the first to third exemplary embodiments. The level of liquid in each evaporation unit 101 is determined by the level of liquid in the second refrigerant tank 107, and does not depend on an amount of heat generated by the electronic device installed in each server rack 100. By using this exemplary embodiment, the volume of refrigerant supplied to the evaporation unit 101 can be optimized by controlling the level of liquid in the second refrigerant tank 107, the controlling the level of liquid in the second refrigerant tank 107 is performed by changing the installation position of the second refrigerant tank 107 along the vertical direction.

Further, in the cooling system according to this exemplary embodiment, the surplus refrigerant 106 in the second refrigerant tank 107 is sent to another second refrigerant tank 107 arranged at a position lower than that of the second refrigerant tank 107 in the vertical lower direction through the branched liquid pipe. The surplus refrigerant 106 in the second refrigerant tank 107 arranged in the lowermost stage among the second refrigerant tanks 107 installed in multi-stage in a height direction is discharged to the refrigerant recovery pipe 109 through the branched liquid pipe. As a result, the level of liquid in the second refrigerant tank 107 is kept to a constant level that is equal to a height of a branching point. As a result, the volume of refrigerant supplied to a plurality of the evaporation units 101 becomes more stable.

In the cooling system according to the second exemplary embodiment, one second refrigerant tank 107 is used for each server rack and the volume of refrigerant supplied to each evaporation unit 101 is uniformly controlled. In contrast, in the cooling system according to this exemplary embodiment, the refrigerant supply volume can be individually controlled for each evaporation unit 101 by using the level of liquid in each second refrigerant tank 107. As a result, the volume of refrigerant supplied to each evaporation unit 101 can be further optimized.

Further, in this exemplary embodiment, in a case in which a data center is of plural-story construction and there is a server room in the downstairs floor, the refrigerant discharged to the refrigerant recovery pipe 109 may be sent to the refrigerant tank in the downstairs server room like the second exemplary embodiment. The refrigerant recovery pipe 109 is extended also toward a left direction in paper of FIG. 4. In a case in which there is a server room in the downstairs floor, the refrigerant recovery pipe 109 extending toward the left direction in paper of FIG. 4 may be connected to the refrigerant tank in the downstairs server room.

### Fifth Exemplary Embodiment

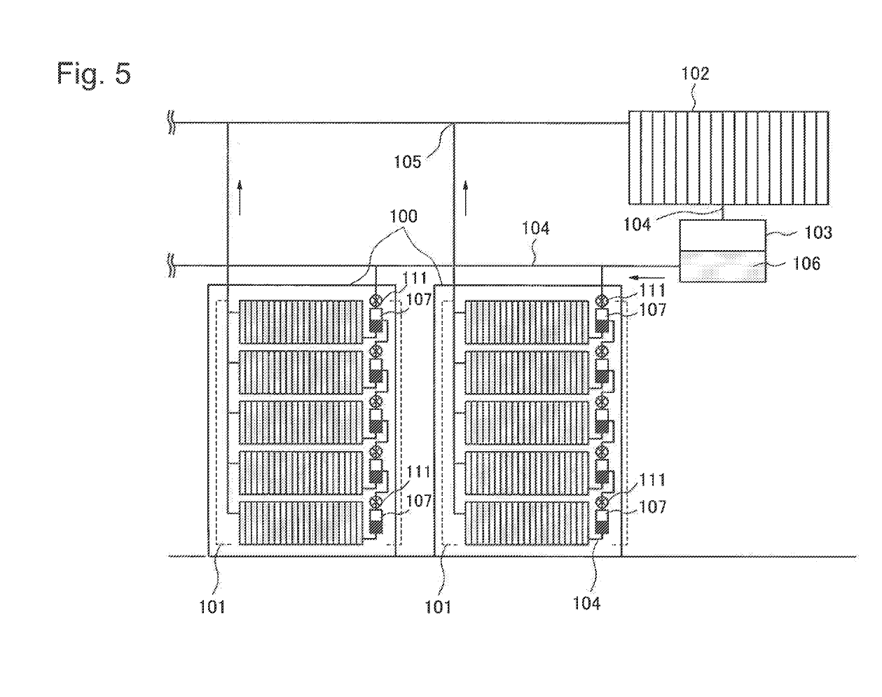

Next, a cooling system according to a fifth exemplary embodiment of the present invention and a method for controlling a refrigerant supply volume in the cooling system will be described. FIG. 5 is a configuration diagram showing the cooling system according to the fifth exemplary embodiment of the present invention. The same reference numbers are added to elements similar to the first to fourth exemplary embodiments, and thereby the detailed description of the element will be omitted. In the cooling system according to this exemplary embodiment, the evaporation units 101, the second refrigerant tanks 107, and the refrigerant supply volume suppression mechanisms 111 according to the third exemplary embodiment are installed in multi-stage in a height direction.

In the cooling system according to this exemplary embodiment, two server racks 100 whose outer shapes are vertically long are installed and a plurality of evaporation units 101 whose outer shapes are horizontally long are arranged in each of two server racks 100 like the fourth exemplary embodiment. In the cooling system according to this exemplary embodiment, the second refrigerant tank 107 and the refrigerant supply volume suppression mechanism 111 are provided for each evaporation unit 101.

Specifically, the cooling system of this exemplary embodiment is a modification example of the cooling system according to the third exemplary embodiment and the fourth exemplary embodiment. The cooling system according to this exemplary embodiment further includes the refrigerant supply volume suppression mechanism 111, which suppresses the refrigerant supply volume according to the level of liquid in the second refrigerant tank 107, located between the refrigerant tank 103 provided as an example of the first refrigerant tank and a plurality of the second refrigerant tanks 107. Further, the cooling system according to this exemplary embodiment includes the refrigerant supply volume suppression mechanism 111, which suppresses the refrigerant supply volume according to the level of liquid in the second refrigerant tank 107, located between the second refrigerant tank 107 and another second refrigerant tank 107 arranged at a position lower than that of the second refrigerant tank 107 in the vertical lower direction as an example of the lower side.

In the cooling system according to this exemplary embodiment, the liquid-phase refrigerant is supplied to each evaporation unit 101 by the gravity naturally like the first to fourth exemplary embodiments. The level of liquid in each evaporation unit 101 is determined by the level of liquid in the second refrigerant tank 107, and does not depend on an amount of heat generated by the electronic device installed in each server rack 100. By using the cooling system according to this exemplary embodiment, the volume of refrigerant supplied to the evaporation unit 101 can be optimized by controlling the level of liquid in the second refrigerant tank 107, and the controlling the level of liquid in the second refrigerant tank 107 is performed by changing the installation position of the second refrigerant tank 107 along the vertical direction or by another method.

Further, in the cooling system according to this exemplary embodiment, the surplus refrigerant 106 in the second refrigerant tank 107 is sent to the another second refrigerant tank 107 arranged at a position lower than that of the second refrigerant tank 107 in the vertical lower direction through the branched liquid pipe. The level of liquid in each second refrigerant tank 107 is kept to a constant level that is equal to a height of the branching point. As a result, the volume of refrigerant supplied to a plurality of the evaporation units 101 becomes more stable.

In the cooling system according to this exemplary embodiment, the second refrigerant tank 107 and the refrigerant supply volume suppression mechanism 111 are arranged for each evaporation unit 101. As a result, not only the refrigerant supply volume of the server rack 100 unit can be optimized but also the refrigerant supply volume of the electronic device unit (for each height) in each server rack 100 can be optimized. In this exemplary embodiment, these two measures are simultaneously performed, and thereby it becomes possible to further optimize the supply of the refrigerant.

### Sixth Exemplary Embodiment

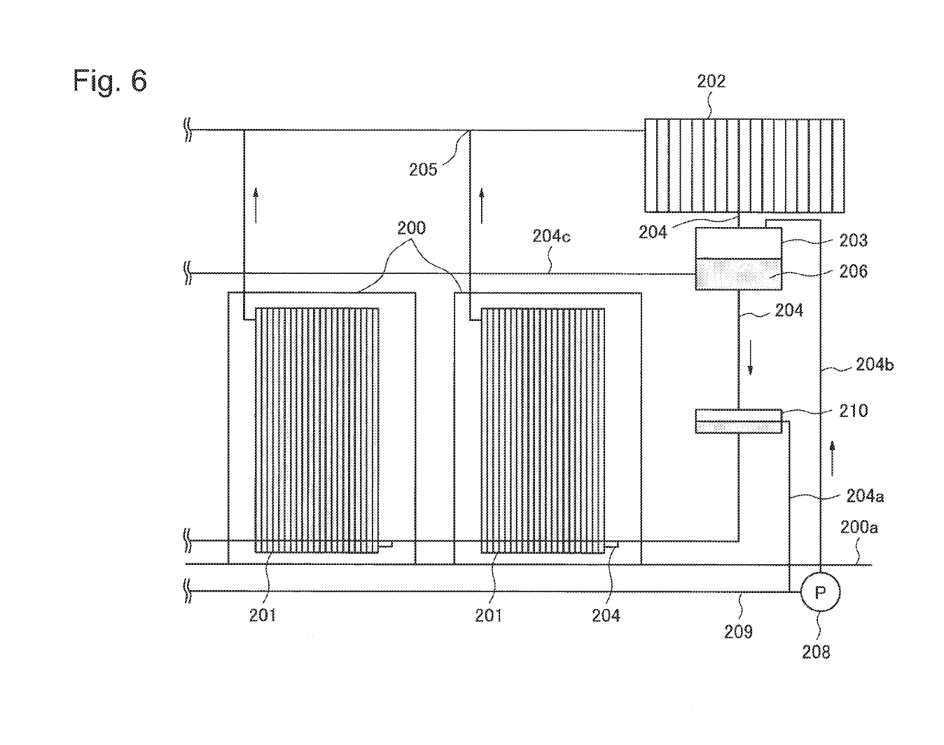

Next, a cooling system according to a sixth exemplary embodiment of the present invention and a method for controlling a refrigerant supply volume in the cooling system will be described. FIG. 6 is a configuration diagram showing the cooling system according to the sixth exemplary embodiment of the present invention. This exemplary embodiment is a modification example of the cooling system according to the second exemplary embodiment. In this exemplary embodiment, a refrigerant tank 203 which has a connection port on the side surface and a connection port on the bottom surface and a second refrigerant tank 210 shared by a plurality of evaporation units 201 are used.

Namely, as shown in FIG. 6, the cooling system according to this exemplary embodiment includes the refrigerant tank 203 provided as an example of the first refrigerant tank which stores a liquid-phase refrigerant 206 and a plurality of evaporation units 201 which gasify the liquid-phase refrigerant supplied from the refrigerant tank 203. Further, the cooling system according to this exemplary embodiment includes a condensation unit 202 which liquefies the gas-phase refrigerant gasified by a plurality of the evaporation units 201 and a vapor pipe 205 which connects the evaporation units 201 and the condensation unit 202 and in which the gas-phase refrigerant flows. Further, the cooling system according to this exemplary embodiment includes a liquid pipe 204 which connects the condensation unit 202 and the refrigerant tank 203 and connects the refrigerant tank 203 and a plurality of the evaporation units 201 and in which the liquid-phase refrigerant flows.

Here, the condensation unit 202 is arranged at a position higher than those of a plurality of the evaporation units 201 in the vertical upper direction as an example of the upper side, and the refrigerant tank 203 is arranged at a position lower than that of the condensation unit 202 in the vertical lower direction as an example of the lower side. The refrigerant tank 203 is arranged at a position higher than those of a plurality of the evaporation units 201 when viewed from an installation surface 200a of a plurality of server racks 200. A heat exchange machine such as a radiator or the like can be used as a plurality of the evaporation units 201 and the condensation unit 202 like the first exemplary embodiment.

A plurality of the evaporation units 201 are arranged on the rear surface or the front surface of the server rack 200. FIG. 6 shows a case in which two server racks 200 whose outer shapes are vertically long are installed and one evaporation unit 201 whose outer shape is vertically long is arranged in each of two server racks 200. The electronic device that is a heat generation source is installed in the server rack 200.

The liquid pipe 204 connects a lower part of the condensation unit 202 and an upper part of the refrigerant tank 203, and connects a bottom surface of the refrigerant tank 203 and a lower part of each evaporation unit 201 via one second refrigerant tank 210. The vapor pipe 205 connects an upper part of each evaporation unit 201 and an upper part of the condensation unit 202. The refrigerant 206 is enclosed in such closed system.

Further, a liquid pipe 204a is branched off from the liquid pipe 204 near the midpoint of the side surface of the second refrigerant tank 210 and the liquid pipe 204a is connected to a refrigerant recovery pipe 209 arranged in a space under the installation surface 200a of the server rack 200 for example, an underfloor space or the like, like the second exemplary embodiment. The refrigerant recovery pipe 209 is connected to the refrigerant tank 203 via a liquid pipe 204b, and a pump 208 is arranged therebetween. A part of the refrigerant 206 in the second refrigerant tank 210 is discharged from near the midpoint of the side surface of the second refrigerant tank 210 to the refrigerant recovery pipe 209 through the liquid pipe 204a. The refrigerant discharged to the refrigerant recovery pipe 209 is returned to the refrigerant tank 203 via the liquid pipe 204b by the operation of the pump 208.

Further, in a case in which a data center is of plural-story construction and there is a server room in the downstairs floor, the pump 208 is not used and the refrigerant discharged to the refrigerant recovery pipe 209 may be sent to the refrigerant tank in the downstairs server room. The refrigerant recovery pipe 209 and a liquid pipe 204c are extended also toward a left direction in paper of FIG. 6. In a case in which there is a server room in the downstairs floor, the refrigerant recovery pipe 209 and the liquid pipe 204c extending toward the left direction in paper of FIG. 6 may be connected to the refrigerant tank in the downstairs server room. Further, the liquid pipe 204c may be connected to another second refrigerant tank different from the second refrigerant tank 210 shown in FIG. 6. Further, a part of the refrigerant 206 in the refrigerant tank 203 is discharged from a lower part of the side surface of the refrigerant tank 203 through the liquid pipe 204c toward a left direction in paper of FIG. 6.

Even in the cooling system according to this exemplary embodiment, the liquid-phase refrigerant is supplied to each evaporation unit 201 by the gravity naturally like the first to fifth exemplary embodiments. The level of liquid in each evaporation unit 201 is determined by the level of liquid in the second refrigerant tank 210, and does not depend on an amount of heat generated by the electronic device installed in each server rack 200. By using this exemplary embodiment, the volume of refrigerant supplied to the evaporation unit 201 can be optimized by controlling the level of liquid in the second refrigerant tank 210, and the controlling the level of liquid in the second refrigerant tank 210 is performed by changing the installation position of the second refrigerant tank 210 along the vertical direction.

Further, in the cooling system according to this exemplary embodiment, the surplus refrigerant 206 in the second refrigerant tank 210 is discharged to the refrigerant recovery pipe 209 through the branched liquid pipe 204a. As a result, the level of liquid in the second refrigerant tank 210 is kept to a constant level that is equal to a height of the branching point. As a result, the volume of refrigerant supplied to a plurality of the evaporation units 201 becomes more stable. By using this exemplary embodiment, the volume of refrigerant supplied to each evaporation unit 201 can be uniformly controlled by controlling the level of liquid in the second refrigerant tank 210, and the controlling the level of liquid in the second refrigerant tank 210 is performed by changing the installation position of the second refrigerant tank 210 along the vertical direction.

Further, in FIG. 6, the liquid pipes 204, 204a, 204b, and 204c and the vapor pipe 205 are drawn as lines extending toward the vertical direction or the horizontal direction. However, it is not necessary to place the liquid pipes 204, 204a, 204b, and 204c and the vapor pipe 205 in a completely horizontal direction or a completely vertical direction.

### Seventh Exemplary Embodiment

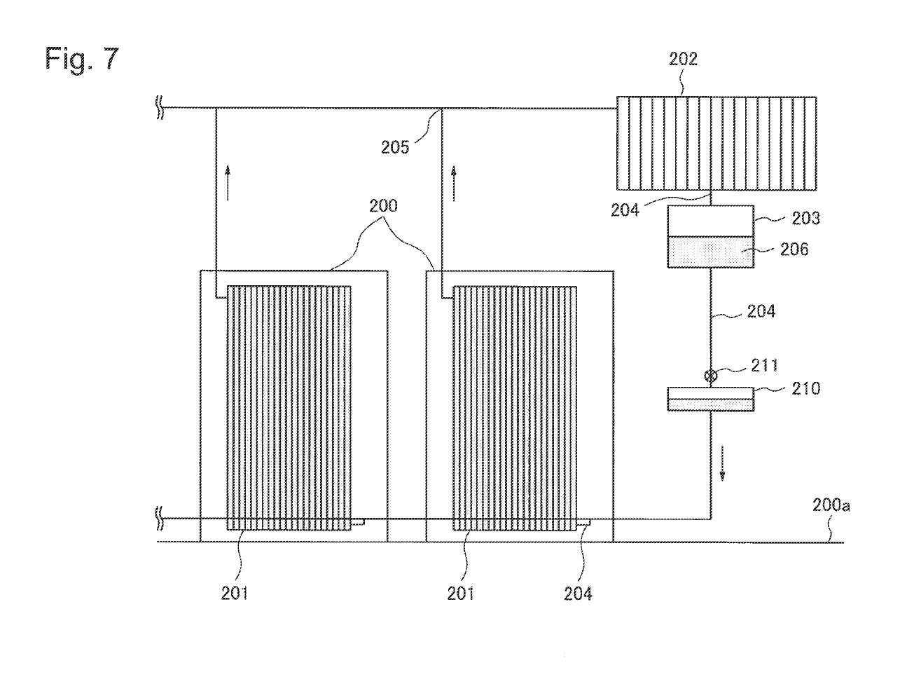

Next, a cooling system according to a seventh exemplary embodiment of the present invention and a method for controlling a refrigerant supply volume in the cooling system will be described. FIG. 7 is a configuration diagram showing the cooling system according to the seventh exemplary embodiment of the present invention. The same reference numbers are added to elements similar to the sixth exemplary embodiment, and thereby the detailed description of the element will be omitted.

This exemplary embodiment further includes a refrigerant control mechanism, which suppresses the refrigerant supply volume according to the level of liquid in the second refrigerant tank 210, located between the refrigerant tank 203 provided as an example of the first refrigerant tank and the second refrigerant tank 210 like the third exemplary embodiment or the fifth exemplary embodiment. Specifically, the refrigerant control mechanism is a refrigerant supply volume suppression mechanism 211 which suppresses the refrigerant supply volume according to the level of liquid in the second refrigerant tank 210.

Even in the cooling system according to this exemplary embodiment, the liquid-phase refrigerant is supplied to each evaporation unit 201 by the gravity naturally like the first to sixth exemplary embodiments. The level of liquid in each evaporation unit 201 is determined by the level of liquid in the second refrigerant tank 210, and does not depend on an amount of heat generated by the electronic device installed in each server rack 200. By using this exemplary embodiment, the operation of the whole cooling system can be optimized by uniformly controlling the volume of refrigerant supplied to the evaporation unit 201 by controlling the level of liquid in the second refrigerant tank 210, and the controlling the level of liquid in the second refrigerant tank 210 is performed by changing the installation position of the second refrigerant tank 210 along the vertical direction.

Further, in this exemplary embodiment, the refrigerant supply volume suppression mechanism 211 monitors the level of liquid in the second refrigerant tank 210 and when the level of liquid is higher than a predetermined level, the refrigerant supply volume suppression mechanism 211 suppresses the supply of the refrigerant to the second refrigerant tank 210 like the third exemplary embodiment or the fifth exemplary embodiment. Accordingly, it becomes possible to control the level of liquid in the second refrigerant tank 210 and the volume of refrigerant supplied to each evaporation unit 201 becomes more stable.

### Eighth Exemplary Embodiment

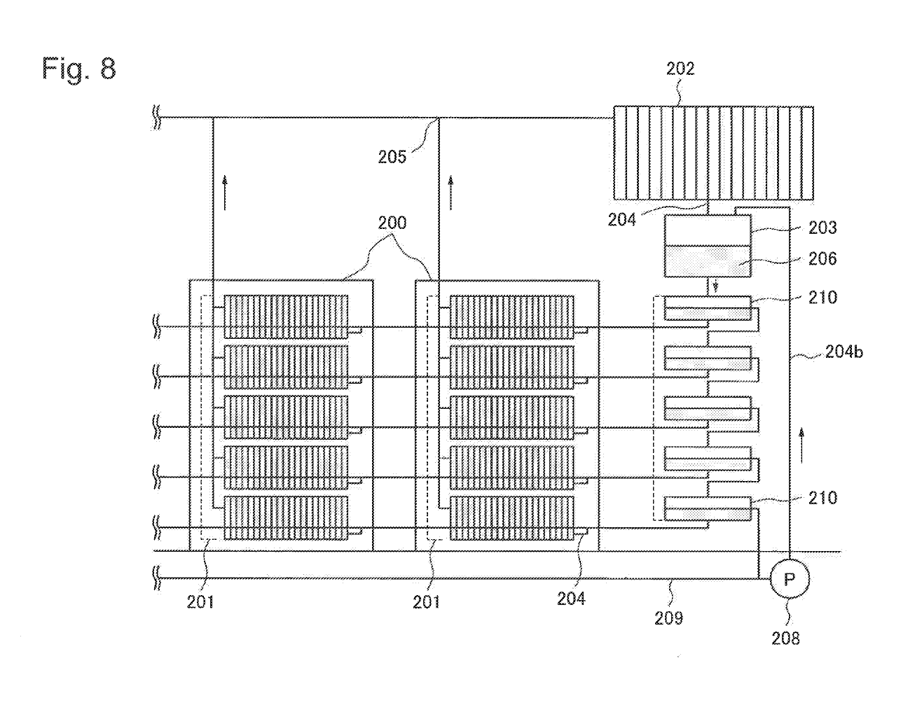

Next, a cooling system according to an eighth exemplary embodiment of the present invention and a method for controlling a refrigerant supply volume in the cooling system will be described. FIG. 8 is a configuration diagram showing the cooling system according to the eighth exemplary embodiment of the present invention. The same reference numbers are added to elements similar to the sixth exemplary embodiment or the seventh exemplary embodiment, and thereby the detailed description of the element will be omitted. In the cooling system according to this exemplary embodiment, the evaporation units 201 and the second refrigerant tanks 210 according to the sixth exemplary embodiment or the seventh exemplary embodiment are installed in multi-stage in a height direction. In the cooling system according to this exemplary embodiment, two server racks 200 whose outer shapes are vertically long are installed and a plurality of evaporation units 201 whose outer shapes are horizontally long are arranged in each of two server racks 200 like the fourth exemplary embodiment or the fifth exemplary embodiment.

As shown in FIG. 8, in the cooling system according to this exemplary embodiment, two server racks 200 whose outer shapes are vertically long are installed and a plurality of evaporation units 201 whose outer shapes are horizontally long are arranged in each of two server racks 200. FIG. 8 shows a case in which five evaporation units 201 are arranged in one server rack 200.

Five second refrigerant tanks 210 are arranged for five evaporation units 201. The refrigerant 206 of one of five second refrigerant tanks 210 is supplied to the evaporation unit 201 from the bottom surface of the second refrigerant tank 210 through the liquid pipe. The second refrigerant tank 210 and the evaporation unit 201 that are arranged at the same height are connected to each other by the liquid pipe 204. The branched liquid pipe that is branched off from the liquid pipe near the midpoint of the side surface of the second refrigerant tank 210 arranged at the upper side is connected to an upper part of the second refrigerant tank 210 arranged at the lower side. The branched liquid pipe that is branched off from the liquid pipe near the midpoint of the side surface of the second refrigerant tank 210 arranged in the lowermost stage among the second refrigerant tanks 210 installed in multi-stage in a height direction is connected to the refrigerant recovery pipe 209.

By such structure, a part of the refrigerant 206 in the second refrigerant tank 210 is supplied to another second refrigerant tank 210 arranged at a position lower than that of the second refrigerant tank 210 in the vertical lower direction as an example of the lower side through the branched liquid pipe that is branched off from the liquid pipe near the midpoint of the side surface of the second refrigerant tank 210. A part of the refrigerant 206 of the second refrigerant tank 210 arranged in the lowermost stage among the second refrigerant tanks 210 installed in multistage in a height direction is discharged from near the midpoint of the side surface of the second refrigerant tank 210 to the refrigerant recovery pipe 209 through the liquid pipe. The refrigerant discharged to the refrigerant recovery pipe 209 is returned to the refrigerant tank 203 provided as an example of the first refrigerant tank via the liquid pipe 204b by the operation of the pump 208.

In this exemplary embodiment, the surplus refrigerant in the second refrigerant tank 210 arranged at the upper side moves to the second refrigerant tank 210 arranged at the lower side through the branched liquid pipe. As a result, it becomes possible not only to optimize the refrigerant supply volume for each server rack 200 but also to optimize the refrigerant supply volume for each electronic device in each server rack 200.

Further, it is not necessary to connect two second refrigerant tanks 210 that are arranged right above or below of each other. Namely, two second refrigerant tanks 210 that are not arranged right above or below of each other can be connected. It is not necessary to connect the refrigerant tank 203 and the second refrigerant tank 210 arranged in an uppermost stage. The refrigerant tank 203 can be connected to the second refrigerant tank 210 arranged in an intermediate stage. The refrigerant tank 203 may not be used. It is not necessary to only connect the refrigerant recovery pipe 209 and the second refrigerant tank 210 arranged in the lowermost stage. The refrigerant recovery pipe 209 can be connected also to the second refrigerant tank 210 arranged in the intermediate stage.

This exemplary embodiment may have the same structure as the second exemplary embodiment or the sixth exemplary embodiment. Namely, in a case in which a data center is of plural-story construction and there is a server room in the downstairs floor, the pump 208 is not used and the refrigerant discharged to the refrigerant recovery pipe 209 may be sent to the refrigerant tank in the downstairs server room. The refrigerant recovery pipe 209 is extended in a left direction of FIG. 8. In a case in which there is the server room in the downstairs floor, the refrigerant recovery pipe 209 extending in the left direction of FIG. 8 may be connected to the refrigerant tank in the downstairs server room.

### Ninth Exemplary Embodiment

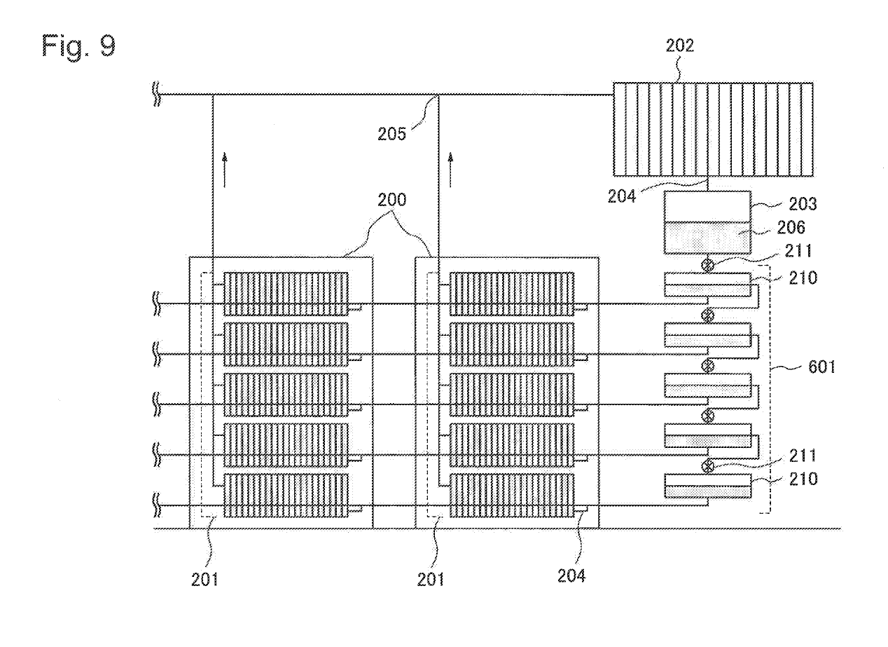

Next, a cooling system according to a ninth exemplary embodiment of the present invention and a method for controlling a refrigerant supply volume in the cooling system will be described. FIG. 9 is a configuration diagram showing the cooling system according to the ninth exemplary embodiment of the present invention. The same reference numbers are added to elements similar to the sixth to eighth exemplary embodiments, and thereby the detailed description of the element will be omitted. In the cooling system according to this exemplary embodiment, the evaporation units 201, the second refrigerant tanks 210, and the refrigerant supply volume suppression mechanisms 211 according to the seventh exemplary embodiment are installed in multi-stage in a height direction.

In the cooling system according to this exemplary embodiment, two server racks 200 whose outer shapes are vertically long are installed and a plurality of evaporation units 201 whose outer shapes are horizontally long are arranged in each of two server racks 200 like the fourth exemplary embodiment, the fifth exemplary embodiment or the eighth exemplary embodiment. In the cooling system according to this exemplary embodiment, the second refrigerant tank 210 and the refrigerant supply volume suppression mechanism 211 are provided for each evaporation unit 201.

The branched liquid pipe that is branched off from the liquid pipe near the midpoint of the side surface of the second refrigerant tank 210 arranged at the upper side is connected to an upper part of the second refrigerant tank 210 arranged at the lower side. A liquid pipe is not branched off from the second refrigerant tank 210 arranged in the lowermost stage among the second refrigerant tanks 210 that are installed in multi-stage in a height direction unlike the eighth exemplary embodiment. The liquid pipe connects each second refrigerant tank 210 and the evaporation unit 201 that are arranged at the same height.

The surplus refrigerant in the second refrigerant tank 210 arranged at the upper side moves to the second refrigerant tank 210 arranged at the lower side through the branched liquid pipe. As a result, not only the refrigerant supply volume of the server rack 200 unit can be optimized but also the refrigerant supply volume can be optimized for each electronic device in each server rack 200.

Further, it is not necessary to connect two second refrigerant tanks 210 that are arranged right above or below of each other. Namely, two second refrigerant tanks 210 that are not arranged right above or below of each other can be connected. It is not necessary to connect the refrigerant tank 203 provided as an example of the first refrigerant tank and only the second refrigerant tank 210 arranged in the uppermost stage. The refrigerant tank 203 can be connected to the second refrigerant tank 210 arranged in the intermediate stage. Further, it is not necessary to provide the refrigerant supply volume suppression mechanisms 211 for all second refrigerant tanks 210.

Although the preferable exemplary embodiments of the present invention has been described above, the present invention is not limited to these exemplary embodiments. Various changes in the configuration or details of the invention of the present application can be made without departing from the scope of the invention described in the claims and the exemplary embodiments to which various changes and modifications are applied are also included in the technical scope of the present invention.

For example, the condensation unit according to the above-mentioned exemplary embodiment is not necessarily arranged at a position higher than those of a plurality of the evaporation units in the vertical upper direction. It may be arranged at a position higher than those of a plurality of the evaporation units in an upper direction. Further, the refrigerant tank according to the above-mentioned exemplary embodiment is not necessarily arranged at a position lower than that of the condensation unit in the vertical lower direction. It may be arranged at a position lower than that of the condensation unit in a lower direction.

Further, a part of or all of the above-mentioned exemplary embodiment can be described as following supplementary notes. However, the present invention is not limited to the following supplementary notes.

(Supplementary note 1) A cooling system including a first refrigerant tank which stores a liquid-phase refrigerant, a plurality of evaporation units which gasify the liquid-phase refrigerant supplied from the first refrigerant tank, a condensation unit which liquefies a gas-phase refrigerant gasified by the evaporation unit, a vapor pipe which connects the evaporation unit and the condensation unit and in which the gas-phase refrigerant flows, and a liquid pipe which connects the condensation unit and the first refrigerant tank and connects the first refrigerant tank and a plurality of the evaporation units and in which the liquid-phase refrigerant flows, wherein the condensation unit is arranged at a position higher than those of a plurality of the evaporation units and the first refrigerant tank is arranged at a position lower than that of the condensation unit.

(Supplementary note 2) The cooling system according to Supplementary note 1, wherein the first refrigerant tank is arranged at a position higher than those of a plurality of the evaporation units.

(Supplementary note 3) The cooling system according to Supplementary note 1 or Supplementary note 2, further including a second refrigerant tank arranged at a position lower than that of the first refrigerant tank.

(Supplementary note 4) The cooling system according to Supplementary note 3, wherein at least a part of the liquid-phase refrigerant stored in the second refrigerant tank flows to the first refrigerant tank.

(Supplementary note 5) The cooling system according to Supplementary note 3 or Supplementary note 4, including a pump which force to flow at least a part of the liquid-phase refrigerant stored in the second refrigerant tank to the first refrigerant tank.

(Supplementary note 6) The cooling system according to any one of Supplementary notes 3 to 5, wherein the second refrigerant tank is provided for each of a plurality of the evaporation units.

(Supplementary note 7) The cooling system according to Supplementary note 6, further including a pump which force to flow a part of the liquid-phase refrigerant stored in the second refrigerant tank to the first refrigerant tank, wherein the pump sends at least a part of the liquid-phase refrigerant stored in the second refrigerant tank provided for each of a plurality of the evaporation units to the first refrigerant tank.

(Supplementary note 8) The cooling system according to any one of Supplementary notes 3 to 5, wherein a plurality of the evaporation units are arranged along a vertical direction, and wherein a plurality of the second refrigerant tanks are arranged along the vertical direction in correspondence with the plurality of the evaporation units arranged along the vertical direction.

(Supplementary note 9) The cooling system described in any one of Supplementary notes 3 to 5, wherein the plurality of the evaporation units are further arranged along a direction different from a vertical direction, and wherein a plurality of the second refrigerant tanks are arranged along the direction different from the vertical direction in correspondence with the plurality of the evaporation units arranged along the direction different from the vertical direction.

(Supplementary note 10) The cooling system according to Supplementary note 8 or Supplementary note 9, wherein a part of the liquid-phase refrigerant stored in one second refrigerant tank among a plurality of the second refrigerant tanks flows to another second refrigerant tank located at a position lower than that of the one second refrigerant tank.

(Supplementary note 11) The cooling system according to any one of Supplementary notes 3 to 9, further includes a pump which force to flow a part of the liquid-phase refrigerant stored in the second refrigerant tank to the first refrigerant tank, and wherein a part of the liquid-phase refrigerant stored in the second refrigerant tank located at the lower side among a plurality of the second refrigerant tanks is force to flow to the first refrigerant tank by the pump.

(Supplementary note 12) The cooling system according to any one of Supplementary notes 3 to 11, wherein the liquid-phase refrigerant flows to a plurality of the evaporation units from one second refrigerant tank among a plurality of the second refrigerant tanks.

(Supplementary note 13) The cooling system according to any one of Supplementary notes 3 to 12, further including a refrigerant control mechanism which is arranged between the liquid pipe which connects the first refrigerant tank and the second refrigerant tank and controls a liquid-phase refrigerant supply volume.

(Supplementary note 14) The cooling system according to any one of Supplementary notes 3 to 12, wherein a plurality of refrigerant control mechanisms which control the liquid-phase refrigerant supply volume are arranged between the liquid pipes which connect a plurality of the second refrigerant tanks and the first refrigerant tank, respectively.

(Supplementary note 15) The cooling system according to Supplementary note 9 or Supplementary note 14, wherein a plurality of the second refrigerant tanks are arranged along the vertical direction, and wherein the refrigerant control mechanism which controls the liquid-phase refrigerant supply volume is arranged in between the liquid pipe which connect one second refrigerant tank and another second refrigerant tank.

(Supplementary note 16) A method for controlling a refrigerant supply volume in a cooling system including a refrigerant tank which stores the liquid-phase refrigerant, a plurality of the evaporation units which gasify the liquid-phase refrigerant supplied from the refrigerant tank, a condensation unit which liquefies a gas-phase refrigerant gasified by the evaporation units, a vapor pipe which connects the evaporation unit and the condensation unit and in which the gas-phase refrigerant flows, and a liquid pipe which connects the condensation unit and the refrigerant tank and connects the refrigerant tank and a plurality of the evaporation units and in which the liquid-phase refrigerant flows, wherein a volume of a liquid-phase refrigerant supplied to the evaporation unit is controlled by changing an arrangement of the refrigerant tank in a vertical direction.

(Supplementary note 17) The method for controlling a refrigerant supply volume in a cooling system according to Supplementary note 16, wherein the volume of the liquid-phase refrigerant supplied to the evaporation unit is controlled by controlling a level of liquid of the liquid-phase refrigerant in the refrigerant tank, and the controlling a level of liquid of the liquid-phase refrigerant in the refrigerant tank is performed by changing a position of the refrigerant tank in the vertical direction.

This application is based upon and claims the benefit of priority from Japanese patent application No. 2013-146401, filed on Jul. 12, 2013, the disclosure of which is incorporated herein in its entirety by reference.

### REFERENCE SIGNS LIST

100, 200 server rack
100a, 200a installation surface
101, 201 evaporation unit
102, 202 condensation unit
103, 203 refrigerant tank
104, 104a, 104b, 204, 204a, 204b, 204c liquid pipe
105, 205 vapor pipe
106, 206 refrigerant
107, 210 second refrigerant tank
108, 208 pump
109, 209 refrigerant recovery pipe
111, 211 refrigerant supply volume suppression mechanism

1. A cooling system comprising:
a first refrigerant tank which stores a liquid-phase refrigerant,
a plurality of evaporation units which gasify the liquid-phase refrigerant supplied from the first refrigerant tank,
a condensation unit which liquefies a gas-phase refrigerant gasified by the evaporation unit,
a vapor pipe which connects the evaporation unit and the condensation unit, and in which the gas-phase refrigerant flows, and
a liquid pipe which connects between the condensation unit and the first refrigerant tank and connects between the first refrigerant tank and a plurality of the evaporation units, and in which the liquid-phase refrigerant flows;
wherein the condensation unit is arranged at a position higher than those of a plurality of the evaporation units and
the first refrigerant tank is arranged at a position lower than that of the condensation unit.

2. The cooling system according to claim 1, wherein the first refrigerant tank is arranged at a position higher than those of a plurality of the evaporation units.

3. The cooling system according to claim 1, further comprising a second refrigerant tank arranged at a position lower than that of the first refrigerant tank.

4. The cooling system according to claim 3, wherein at least a part of the liquid-phase refrigerant stored in the second refrigerant tank flows to the first refrigerant tank.

5. The cooling system according to claim 3, comprising a pump which force to flow at least a part of the liquid-phase refrigerant stored in the second refrigerant tank to the first refrigerant tank.

6. The cooling system according to claim 3, wherein the second refrigerant tank is provided for each of a plurality of the evaporation units.

7. The cooling system according to claim 6, further comprising a pump which force to flow a part of the liquid-phase refrigerant stored in the second refrigerant tank to the first refrigerant tank, and
wherein the pump sends at least a part of the liquid-phase refrigerant stored in the second refrigerant tank provided for each of a plurality of the evaporation units to the first refrigerant tank.

8. The cooling system according to claim 3, wherein a plurality of the evaporation units are arranged along a vertical direction, and wherein a plurality of the second refrigerant tanks are arranged along the vertical direction in correspondence with a plurality of the evaporation units arranged in the vertical direction.

9. The cooling system according to claim 3, wherein a plurality of the evaporation units are further arranged along a direction different from a vertical direction, and wherein a plurality of the second refrigerant tanks are arranged in correspondence with the plurality of the evaporation units arranged along the direction different from the vertical direction.

10. (canceled)

11. The cooling system according to claim 3, further comprises a pump which force to flow a part of the liquid-phase refrigerant stored in the second refrigerant tank to the first refrigerant tank, and wherein a part of the liquid-phase refrigerant stored in the second refrigerant tank located at the lower side among a plurality of the second refrigerant tanks is force to flow to the first refrigerant tank by the pump.

12. The cooling system according to claim 3, wherein the liquid-phase refrigerant flows to a plurality of the evaporation units from one second refrigerant tank among a plurality of the second refrigerant tanks.

13. The cooling system according to claim 3, further comprising a refrigerant control mechanism which is arranged between the liquid pipe which connects the first refrigerant tank and the second refrigerant tank and controls a liquid-phase refrigerant supply volume.

14. The cooling system according to claim 3, wherein a plurality of refrigerant control mechanisms which control the liquid-phase refrigerant supply volume are arranged between the liquid pipes which connect a plurality of the second refrigerant tanks and the first refrigerant tank, respectively.

15. The cooling system according to claim 8, wherein a part of the liquid-phase refrigerant stored in one second refrigerant tank among a plurality of the second refrigerant tanks flows to another second refrigerant tank located at a position lower than that of the one second refrigerant tank.

16. The cooling system according to claim 9, wherein a plurality of the second refrigerant tanks are arranged along the vertical direction, and wherein the refrigerant control mechanism which controls the liquid-phase refrigerant supply volume is arranged in between the liquid pipe which connect one second refrigerant tank and another second refrigerant tank.

17. A method for controlling a refrigerant supply volume in a cooling system comprising a refrigerant tank which stores the liquid-phase refrigerant, a plurality of the evaporation units which gasify the liquid-phase refrigerant supplied from the refrigerant tank, a condensation unit which liquefies a gas-phase refrigerant gasified by the evaporation units, a vapor pipe which connects the evaporation unit and the condensation unit and in which the gas-phase refrigerant flows, and a liquid pipe which connects the condensation unit and the refrigerant tank and connects the refrigerant tank and a plurality of the evaporation units and in which the liquid-phase refrigerant flows,
wherein a volume of a liquid-phase refrigerant supplied to the evaporation unit is controlled by changing an arrangement of the refrigerant tank in a vertical direction.

18. The method for controlling a refrigerant supply volume in a cooling system according to claim 17, wherein the volume of the liquid-phase refrigerant supplied to the evaporation unit is controlled by controlling a level of liquid of the liquid-phase refrigerant in the refrigerant tank, and the controlling a level of liquid of the liquid-phase refrigerant in the refrigerant tank is performed by changing a position of the refrigerant tank in the vertical direction.
